(19) United States
(12) Patent Application Publication
(10) Pub. No.: US 2014/0052397 A1
(43) Pub. Date: Feb. 20, 2014

(54) INRUSH CURRENT MEASURING DEVICE

(71) Applicants: Po Yin CHAO, Taipei (TW); Kuo Yuan YUAN, Taipei (TW); Yao-Jen CHANG, Taipei (TW); Yi-Ta HSIEH, Taipei (TW)

(72) Inventors: Po Yin CHAO, Taipei (TW); Kuo Yuan YUAN, Taipei (TW); Yao-Jen CHANG, Taipei (TW); Yi-Ta HSIEH, Taipei (TW)

(21) Appl. No.: 13/589,210

(22) Filed: Aug. 20, 2012

(51) Int. Cl. G01R 19/00

(52) U.S. Cl. 702/64

(57) ABSTRACT

An inrush current measuring device is disclosed in the present invention. The device includes a current sensing unit, an analog-to-digital converter, a filter, a microcontroller, and a display unit. The inrush current measuring device of the present invention can determine an inrush current by use of at least five sampling current values and does not need to depend on an observation starting point for detecting current value of the inrush current or a continuous detecting time period to obtain accurate measurement of inrush current.

### FIELD OF THE INVENTION

The present invention relates to a current measuring device. More particularly, the present invention relates to an inrush current measuring device for of power supply system of motors or electromechanical devices.

### BACKGROUND OF THE INVENTION

Inrush current refers to the maximum, instantaneous input current drawn by an electrical device when first turned on. It is commonly seen in power supply systems of motors or electromechanical devices. When the motors or electromechanical devices are initiated, instantaneously, a large current occurs. Sometimes, the inrush current can be five to ten times higher than the steady state operation current which exits shortly after the motors or electromechanical devices are warmed up. Voltage of the power supply system fluctuates as the inrush current appears. The inrush current will cause damage to the whole system if no proper protection is performed.

Most prior arts focus on how to avoid or reduce inrush currents, whereas measurement of inrush current is rarely mentioned. In the measurement of inrush current, the measured values vary widely because the timing of occurrence of inrush current cannot be controlled, so sampling is made several times and the maximum value is determined as inrush current, and thus much time is required for grasping the exact value. In some conventional instantaneous power interruption devices, there was difference between the set interruption timing and the actually interrupted instance, influenced for example by a counter electromotive force from the sample.

Although there are observation devices, e.g. oscilloscope, for instantaneously stopping a power supply and checking the characteristic thereof, such an observation device is only suitable for measuring iterative waveforms, but is unsuitable for measuring a waveform which is generated only once.

In power interruption devices of this sort, a switching circuit section is provided halfway on the line for feeding a commercial power supply to a power unit, and by opening or closing the switching circuit section, the power supply is turned off or on, in which a high voltage is applied to the external power input terminal to which is connected the commercial power supply, and also to the external power output terminal to which is connected the power unit under test. Thus, since a high voltage is applied to the external power input and output terminals, it is necessary that the work associated with the external input terminal be done after cutting off the commercial power supply completely, and that the work associated with the external power output terminal be performed after completely cutting off the foregoing switching circuit section of the power interruption device. To this end, it is necessary to take some measure so that the workers can be aware that power is fed to the external power input and output terminals. But the measures so far taken for this purpose were not appropriate, which led to unforeseen accidents.

In other words, traditional inrush current measurement mainly requires an observation starting point for detecting current value of the inrush current or a continuous detecting time period to obtain accurate measurement of inrush current.

For example, U.S. Pat. No. 6,628,113 discloses a method and apparatus for accurately measuring surge currents such as motor-starting inrush currents, as shown in FIG. 1. An input signal from a current sensor is monitored, and when the input signal changes and exceeds a predetermined threshold, a surge current is detected. The input signal is acquired over a predetermined time period by a fast sampling ADC, which converts the input signal into a series of digitized samples representative of instantaneous current values. These values are processed to compute average current or RMS current, which is then displayed.

It is obvious from the description of the invention that a predetermined threshold and time period are both required. However, before the threshold is found, the inrush current might already exist. Thus, a complete and accurate measurement of the inrush current is hard to be obtained.

Hence, a more accurate measuring device for measuring inrush current without limitation of the threshold and time period is desperately needed.

### SUMMARY OF THE INVENTION

This paragraph extracts and compiles some features of the present invention; other features will be disclosed in the follow-up paragraphs. It is intended to cover various modifications and similar arrangements included within the spirit and scope of the appended claims.

In accordance with an aspect of the present invention, an inrush current measuring device includes a current sensing unit for receiving a current and producing a voltage signal proportional to the current received; an analog-to-digital converter, electrically connected to the current sensing unit, for amplifying or attenuating the voltage signal, converting the voltage signal from analog to digital and adjusting current sampling; a filter, electrically connected to the analog-to-digital converter, for adjusting current sampling in order to control an output rate of the digital voltage signal from the analog-to-digital converter; a microcontroller, electrically connected to the filter, for calculating a corresponding current value according to the digital voltage signal and outputting the current value; and a display unit, electrically connected to the microcontroller, for encoding current value for a display.

Preferably, the current sampling occurs in a time unit.

Preferably, the time unit equals to several power signal cycles.

Preferably, the power signal cycle is 20 ms or 16.67 ms.

Preferably, the filter is a comb filter.

Preferably, the comb filter is a fourth-order comb filter.

Preferably, inrush current measuring device further comprises a multiplexer, installed between the current sensing unit and the analog-to-digital converter, for switching different channels of signals.

Preferably, inrush current measuring device further comprises a memory module, electrically connected to the microcontroller, for storing the current value.

Preferably, inrush current measuring device further comprises an I/O control unit, electrically connected to the microcontroller, for controlling input and output of the current value.

Preferably, the display is a liquid crystal display (LCD) monitor.

### BRIEF DESCRIPTION OF THE DRAWINGS

FIG. 1 shows a prior art of an inrush current measuring device.

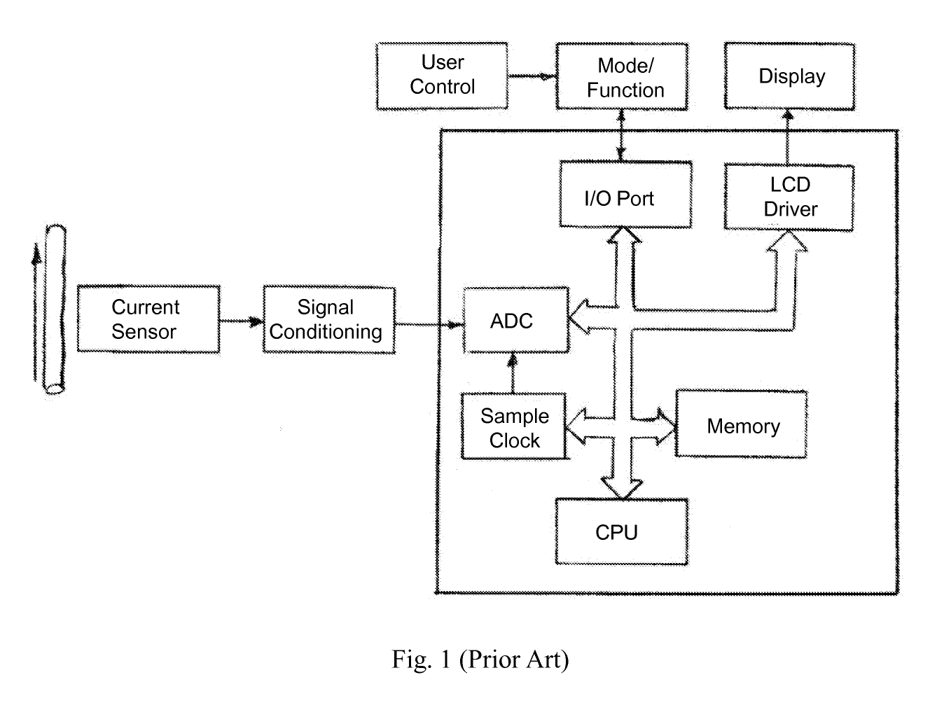

FIG. 2 is an inrush current measuring device of an embodiment according to the present invention.

FIG. 3 is a phenomenon of inrush currents.

### DETAILED DESCRIPTION OF THE PREFERRED EMBODIMENT

The present invention will now be described more specifically with reference to the following embodiment. It is to be noted that the following descriptions of preferred embodiment of this invention are presented herein for purpose of illumination and description only; it is not intended to be exhaustive or to be limited to the precise form disclosed.

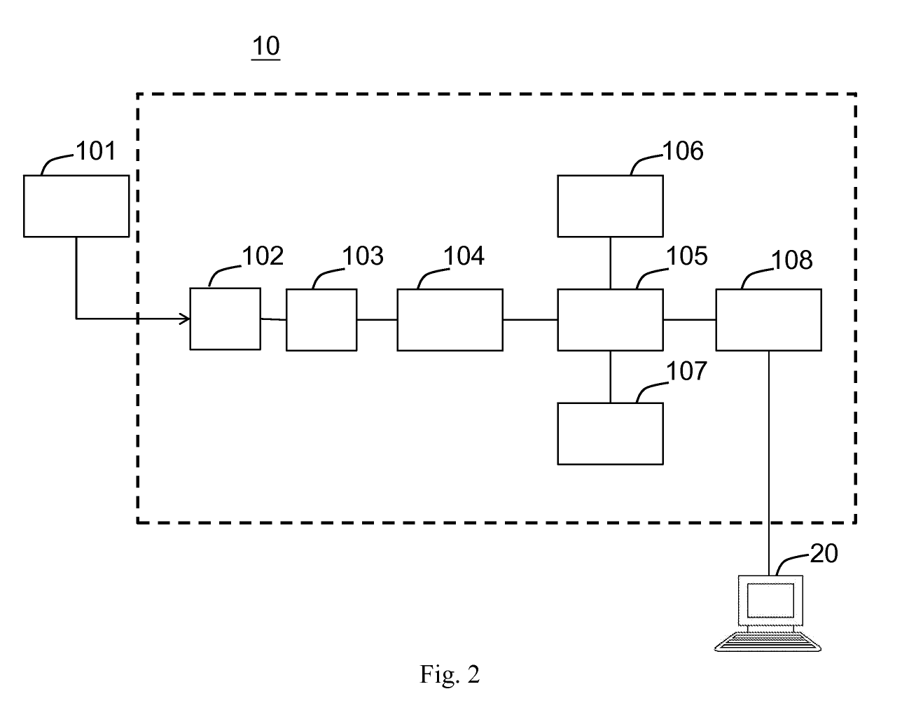

Please refer to FIG. 2. An inrush current measuring device of an embodiment according to the present invention is disclosed. An inrush current measuring device 10 includes a current sensing unit 101, a multiplexer 102, an analog-to-digital converter 103, a filter 104, a microcontroller 105, a memory module 106, an I/O control unit 107 and a display unit 108. The multiplexer 102, analog-to-digital converter 103, filter 104, microcontroller 105, memory module 106, I/O control unit 107 and display unit 108 can be consolidated into a single integrated circuit chip (enclosed by a dashed line in FIG. 2) in practice.

The current sensing unit 101 receives a current from an external power supply and produces a voltage signal proportional to the received current. Generally, a current transducer can be used for this purpose. Preferably, a Hall-effect device or a coil can also be used. In this embodiment, the current sensing unit 101 is a Hall-effect device. The analog-to-digital converter 103 is electrically connected to the current sensing unit 101 for amplifying or attenuating the voltage signal, and converting the voltage signal from analog to digital. Moreover, the analog-to-digital converter 103 can be used for adjusting current sampling which enhances resolution of the analog-to-digital converter 103 when analog-to-digital processes are carried out.

In practice, the current sampling occurs in a time unit. The time unit equals to several power signal cycles. For different system, the power signal cycle can be different. For example, in Europe, the AC power system runs at 60 Hz, the power signal cycle is 20 ms. In Taiwan, AC power system runs at 50 Hz, the power signal cycle is 16.67 ms.

The multiplexer 102 is installed between the current sensing unit 101 and the analog-to-digital converter 103. When more than one current sensing units 101 are used to measure current, namely, the inrush current measuring device 10 can measure inrush current in different devices, the multiplexer 102 can switch different channels of signals inputted so that different values of inrush currents can be obtained at the same time. Simply, a chopper can be used to play the role of the multiplexer 102.

The filter 104 is electrically connected to the analog-to-digital converter 103. It can adjust current sampling in order to control an output rate of the digital voltage signal from the analog-to-digital converter 103. The filter 104 is a comb filter. Preferable, the comb filter is a fourth-order comb filter. The current sampling is controlled by an output code in the filter 104.

The microcontroller 105 is electrically connected to the filter 104. It can calculate a corresponding current value according to the digital voltage signal and output the current value. The spirit of the present invention is to collect at least five current values to determine an inrush current. The output of the current values which reflect the collected five current values during inrush current occurrence stands for the value of the inrush current.

The memory module 106 is electrically connected to the microcontroller 105 for storing the current value from the microcontroller 105. The I/O control unit 107 is electrically connected to the microcontroller 105 for controlling input and output of the current value from the microcontroller 105. For example, users can choose a display mode, blinking LEDs or displaying on a monitor by pressing a button on a control panel (not shown). The I/O control unit 107 can also choose which wire linked should be monitored for measuring inrush current if more than one current sensing units 101 are used. The display unit 108 is electrically connected to the microcontroller 105. It encodes the current value for a display. In this embodiment, the display is a liquid crystal display (LCD) monitor 20. It should be noticed that the display method is dominated by the I/O control unit 107. Meaning that the current value is encoded by the display unit 108 based on the instruction from the I/O control unit 107. The encoded current value can also be displayed on an LED module (not shown).

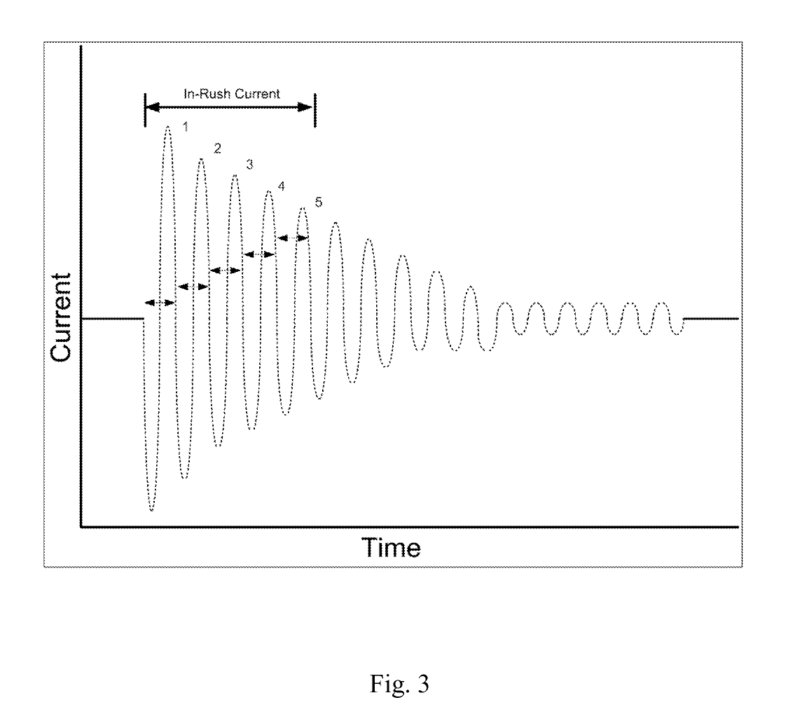

In order to get a better understanding how the inrush current measuring device 10 calculates inrush current, please refer to FIG. 3. It shows a phenomenon of inrush currents. In the present embodiment, the oversampling rate of the analog-to-digital converter 103 is set to be 32. Low pass filter band width is 256. The clock of the analog-to-digital converter 103 is 400 KHz. Root mean square output rate of the inrush current measuring device 10 is 48.82 Hz (1 output in 20.48 ms) (RMS output rate=clock of the analog-to-digital converter 103/oversampling rate of the analog-to-digital converter 103/low pass filter band width=400 KHz/32/256=48.82 Hz)

When inrush current happens, the largest 5 currents (marked in 1˜5 in FIG. 3) are taken to calculate the RMS inrush current. It is

$$Inrush Current = \sqrt{\frac{{I}_{1}^{2} + {I}_{2}^{2} + {I}_{3}^{2} + {I}_{4}^{2} + {I}_{5}^{2}}{5}} ,$$

where I₁, I₂, I₃, I₄ and I₅ are respective largest currents. This process takes around 102.4 ms.

Of course, the settings mentions above can be adjusted in order to have different RMS output rate. Thus, the larger the RMS output rate is, the more inrush current values can be obtained. It is a benefit for the present invention to be applied to different AC power system.

While the invention has been described in terms of what is presently considered to be the most practical and preferred embodiment, it is understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. An inrush current measuring device, comprising:
a current sensing unit for receiving a current and producing a voltage signal proportional to the current received;
an analog-to-digital converter, electrically connected to the current sensing unit, for amplifying or attenuating the voltage signal, converting the voltage signal from analog to digital and adjusting current sampling;
a filter, electrically connected to the analog-to-digital converter, for adjusting current sampling in order to control an output rate of the digital voltage signal from the analog-to-digital converter;
a microcontroller, electrically connected to the filter, for calculating a corresponding current value according to the digital voltage signal and outputting the current value; and
a display unit, electrically connected to the microcontroller, for encoding current value for a display.

2. The inrush current measuring device according to claim 1, wherein the current sampling occurs in a time unit.

3. The inrush current measuring device according to claim 2, wherein the time unit equals to several power signal cycles.

4. The inrush current measuring device according to claim 3, wherein the power signal cycle is 20 ms or 16.67 ms.

5. The inrush current measuring device according to claim 1, wherein the filter is a comb filter.

6. The inrush current measuring device according to claim 5, wherein the comb filter is a fourth-order comb filter.

7. The inrush current measuring device according to claim 1, further comprising a multiplexer, installed between the current sensing unit and the analog-to-digital converter, for switching different channels of signals.

8. The inrush current measuring device according to claim 1, further comprising a memory module, electrically connected to the microcontroller, for storing the current value.

9. The inrush current measuring device according to claim 1, further comprising an I/O control unit, electrically connected to the microcontroller, for controlling input and output of the current value.

10. The inrush current measuring device according to claim 1, wherein the display is a liquid crystal display (LCD) monitor.
